(19) United States
(12) Patent Application Publication
(10) Pub. No.: US 2021/0303763 A1
(43) Pub. Date: Sep. 30, 2021

(54) SYSTEMS AND METHODS FOR GEOMETRY SIMPLIFICATION AND FILTERING

(71) Applicant: MappedIn Inc., Waterloo (CA)

(72) Inventors: Adam Hartfiel, Kitchener (CA); James Nathan Swidersky, Kitchener (CA); Erkang Wei, Waterloo (CA); Paul Bernhardt, Kitchener (CA)

(21) Appl. No.: 17/214,008

(22) Filed: Mar. 26, 2021

Related U.S. Application Data
(60) Provisional application No. 63/000,236, filed on Mar. 26, 2020.

(51) Int. Cl. G06F 30/27; G06F 30/10; G06N 3/08; G06N 3/04

(52) U.S. Cl. CPC G06F 30/27; G06N 3/0454; G06N 3/088; G06F 30/10

(57) ABSTRACT

Computer-implemented systems and methods for geometry simplification and filtering are provided. The systems and methods may provide for automated simplification and filtering of visually complex architectural diagrams to their most important features, as may be desirable for creating maps that are true to real world instantiations. The method may use a conditional generative adversarial network (cGAN) that may be particularly well suited to identifying geometry in feature-poor architectural drawings.

### TECHNICAL FIELD

The embodiments disclosed herein relate to morphological image processing, and in particular to computer-implemented systems and methods for geometry simplification and filtering.

### INTRODUCTION

Design files (e.g. CAD, SVG, DXF) are used to create, draft, edit, modify and optimize the design of buildings, machines, electronics, vehicles and other three-dimensional objects in a number of industries. Raw architectural design files can provide a wealth of geometric data about the design and physical instantiation of the three-dimensional object represented in the drawing. In the context of automatically processing and understanding these designs, the geometric data presented in the design file can be overwhelming and visually confusing.

In some cases, a simplified version of the drawing is desired that includes detail and accuracy at a level similar to the original drawing but that excludes certain features (e.g. geometric data) that are not useful to the application. Existing approaches utilize humans to perform tasks manually, such as by identifying important features or elements in the original drawing or creating a reduced representation by comparing an original drawing and a simplified drawing and filtering unimportant features out. These approaches can be costly, time-consuming, prone to human error, and may produce drawings that have lower accuracy than desired (e.g. failure to adequately preserve geometric relationships between components).

A further difficulty is that architectural design files can be feature-poor, for example, lacking colour or texture. Such features are often used by image processing techniques, such as neural networks, to discriminate between elements.

Accordingly, there is a need for improved systems and methods for generating simplified geometry from source data which preserves geometric relationships between components and a has similar specificity to the source data.

### SUMMARY

According to an aspect, there is a system for geometry simplification and filtering comprising a memory having stored thereon processor-executable instructions that cause a processor to: transform vector imagery into an agnostic representation; generate a raster image, whereby the coordinate system of the agnostic representation is mapped and scaled to an image space; generate a simplified geometry from the raster image; vectorize the simplified geometry in the coordinate system of the image space; generate an approximate reduced representation of the simplified geometry in model space; apply morphological buffering to the approximate reduced representation to generate a buffered approximate reduced representation; and filter the buffered approximate reduced representation to a subset of the vector imagery.

According to another aspect, there is a method for geometry simplification and filtering. The method may be used to simplify and filter geometric information in an architectural drawing (e.g. drawing file including a vector image) to identify important features which can then be used to create maps that are true to real world instantiations.

The method includes transforming vector imagery into an agnostic representation. The vector imagery may be contained in an electronic drawing file. The vector imagery may be greyscale or black and white. The agnostic representation may be a generic geometry collection of the vector imagery in virtual model space

The method includes generating a raster image, whereby the coordinate system of the agnostic representation is mapped and scaled to an image space. The raster image may be represented as a 3×3 invertible matrix in the image space. The coordinate system of the agnostic representation and the raster image may have the same dimensions and be scaled 1-to-1. The agnostic representation may have dimensions of 2048×2048 units and the raster image may have dimensions of 2048×2048 pixels.

The method includes generating a simplified geometry from the raster image using a neural network. The neural network may be a conditional generative adversarial neural network. The neural network may be Pix2PixHD. The method may further include training the neural network to generate a simplified geometry, wherein the simplified geometry includes features in the vector imagery that are deemed important by human trainers. The neural network may be a neural network trained to identify important features in the raster image using training data comprising examples with important features labelled by a human.

The method also includes vectorizing the simplified geometry in the coordinate system of the image space; generating an approximate reduced representation of the simplified geometry; generating a morphologically buffered approximate reduce representation; and filtering the buffered approximate reduce representation to a subset of the original source file geometry. The morphological buffering may be done using epsilon >0.

Other aspects and features will become apparent, to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIG. 1 is a flowchart of a method of geometry simplification and filtering, according to an embodiment;

FIG. 2 is an example source data file including a vector image comprising original geometry which serves as an input to the method of FIG. 1;

FIG. 3 is an example simplified drawing of the vector image of FIG. 1, generated using the method of FIG. 1, according to an embodiment;

FIG. 4 is an example filtered drawing of the vector image of FIG. 1, generated using the method of FIG. 1, according to an embodiment;

FIG. 5 is a block diagram of a computer-implemented system for geometry simplification and filtering, according to an embodiment; and

FIG. 6 is a flow chart of a method for geometry simplification and filtering, according to an embodiment.

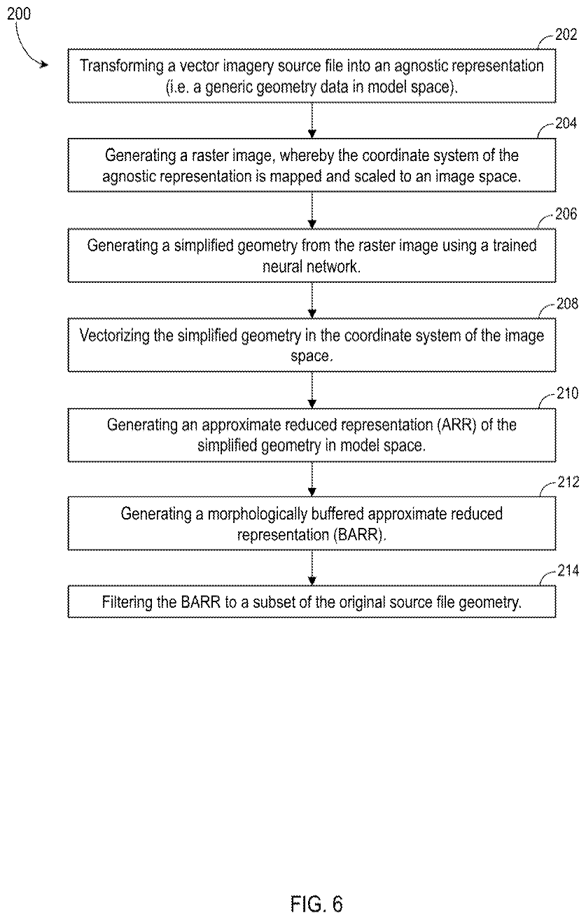

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

One or more systems described herein may be implemented in computer programs executing on programmable computers, each comprising at least one processor, a data storage system (including volatile and non-volatile memory and/or storage elements), at least one input device, and at least one output device. For example, and without limitation, the programmable computer may be a programmable logic unit, a mainframe computer, server, and personal computer, cloud-based program or system.

Each program is preferably implemented in a high-level procedural or object oriented programming and/or scripting language to communicate with a computer system. However, the programs can be implemented in assembly or machine language, if desired. In any case, the language may be a compiled or interpreted language. Each such computer program is preferably stored on a storage media or a device readable by a general or special purpose programmable computer for configuring and operating the computer when the storage media or device is read by the computer to perform the procedures described herein.

A description of an embodiment with several components in communication with each other does not imply that all such components are required. On the contrary a variety of optional components are described to illustrate the wide variety of possible embodiments of the present invention.

Further, although process steps, method steps, algorithms or the like may be described (in the disclosure and/or in the claims) in a sequential order, such processes, methods and algorithms may be configured to work in alternate orders. In other words, any sequence or order of steps that may be described does not necessarily indicate a requirement that the steps be performed in that order. The steps of processes described herein may be performed in any order that is practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

The following relates generally to morphological image processing, and in particular to computer-implemented systems and methods for geometry simplification and filtering.

In embodiments described herein, there is provided a conditional generative adversarial (neural) network-based system and method for automated simplification of visually complex architectural diagrams to their most important components as desirable for creating maps that are true to real world instantiations.

Human faculties seem to perform some sort of subconscious process that recognizes the truly important components of a drawing or diagram. Machine learning provides tools that can be used to mimic this process. The resulting machine learning models, however, perform best within narrowly defined domains. Such networks may transform raster images from one domain to another, such as from rasterized images to simplified building geometry. This transformation attempts to generate an image in the target domain conditioned on the input image, which can be noisy. Further, transforming the result to a vector image is unlikely to preserve the exact details of the building. Image processing neural networks often use features, such as colour or texture, to discriminate between elements. Such features are often lacking in architectural design files.

The systems and methods described herein may have various applications.

For example, the system and methods of the present disclosure may have particular application in the field of electronic indoor mapping. For example, it may be desired to create an electronic indoor map of a facility which includes details of indoor features of the facility, such as store units, washrooms, etc. In this context, these indoor features may be characterized as “important”. Conversely, the facility may include additional features, for example outdoor feature such as parking spaces and roads, which are not relevant or desired for inclusion in the electronic indoor map. In this context, these outdoor features (or other features, as the case may be) may be characterized as “unimportant”. One or more architectural design files, such as a CAD drawing, may exist of the facility which includes geometrical data that can be leveraged to generate an electronic indoor map that has an acceptable level of detail or accuracy. The electronic indoor map will ideally preserve the geometrical relationships between components to produce an accurate representation of the facility. The inclusion of geometrical data in the design file related to unimportant features, such as the outdoor features, however, can increase the complexity of the drawing significantly and is not needed for the electronic indoor mapping purposes. The present disclosure thus provides, in an embodiment, a system and method which can generate a reduced representation of the facility from a source design file which includes a vector image including important and unimportant features. The reduced representation is a filtered version of the original image which includes important features and excludes unimportant features and which preserves the geometrical relationships between surviving important features or elements.

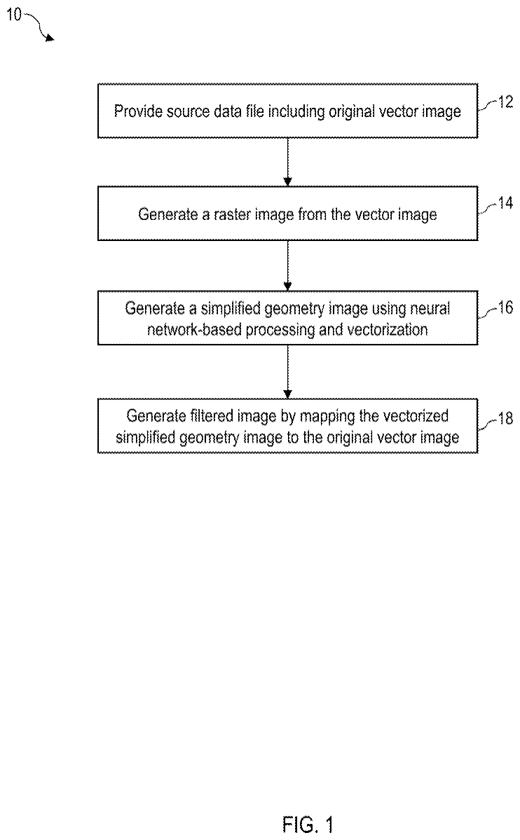

Referring now to FIG. 1, shown therein is a method 10 for geometry simplification and filtering, according to an embodiment. The method 10 may be implemented using one or more computing devices. For example, the steps of method 10 may be implemented as computer-executable instructions which, when executed by a processor of the executing computing device, cause the computing device to perform the steps of the method 10.

Generally, the method 10 can be used to generate a reduced representation of a source data file using geometry simplification and filtering which preserves geometrical relationships between surviving elements and which has the same or similar specificity to the source data file.

At 12, a source data file is provided.

The source data file may be feature-poor. For example, the source data file may lack colour (e.g. black and white, greyscale) or texture.

The source data file includes a vector image comprising vector data. The vector data may be messy. Messiness in this context means the vector data may include elements and features that are visually confusing while not actually part of the building or object depicted in the vector image. These elements and features are generally not required or desired in the eventual reduced representation generated by the method 10. For example, this may include extraneous content such as dimension annotations, ‘thought’ bubbles around planned components, and human errors (e.g. stray lines, things that go beyond implicit visual boundaries), and fine details of regions (e.g. bathroom fixtures, parking lot lines or individual stairs). This undesired content present in the vector data may be considered unimportant features (as further described below).

The vector image is a visual representation of a facility. The facility may be a shopping mall, commercial building, industrial complex, residential building, stadium complex, or other structure. The facility may include indoor components (e.g. a building with multiple units) and outdoor components (e.g. parking lots, roadways, sidewalks, etc.).

The subject matter of the vector image (i.e. what the image is visually representing) is not particularly limited and in other embodiments may be a structure, object, machine, apparatus, or the like.

The vector image includes “important” features and “unimportant” features. An “important feature” as used herein refers to an element or feature of the source data which is to be included in the reduced representation generated by the method 10. An “unimportant feature” as used herein refers to an element or feature of the source data which is not intended to be included in the reduced representation, and thus is intended to be or should be excluded from the reduced representation. In this sense, the method 10 ideally generates a reduced representation which includes only important features (and excludes unimportant features).

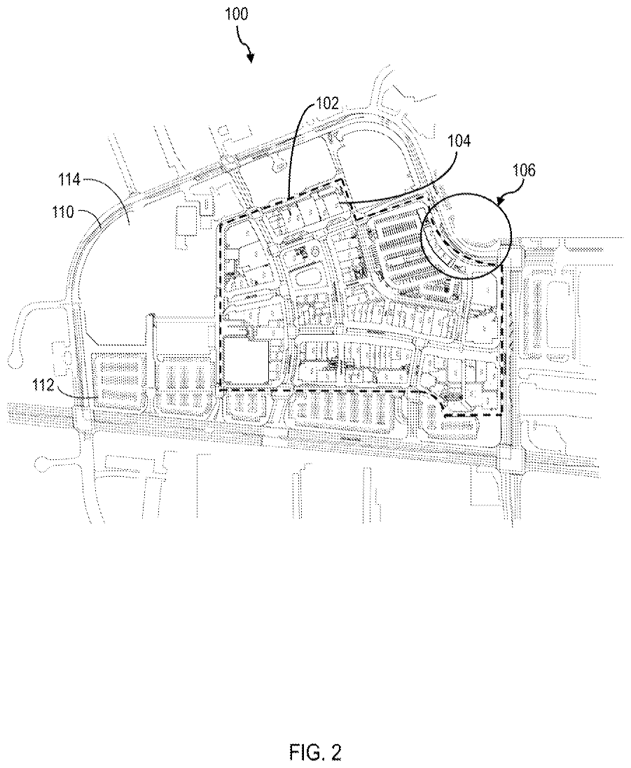

An example vector image input is shown in FIG. 2. FIG. 2 illustrates an example original drawing 100 of a shopping facility 102 (area bounded by the dashed line) and surrounding areas. The surrounding areas may include the area surrounding the shopping facility 102 that is still part of the property on which the shopping facility 102 is situated. In variations of the present disclosure, the shopping facility 102 may be any type of facility. The type of facility is not particularly limited, however, the systems and methods of the present disclosure may have particular application in mapping large indoor facilities with several units, such as a shopping mall or the like.

The shopping facility 102 includes a plurality of store units (representative store unit 104 is shown). The surrounding areas includes roads 110, parking spaces 112 and vacant land 114.

The original drawing 100 is from a design file. The design file may be a CAD file. The design file may be a file in which each line in the drawing is represented as vector imagery.

The vector imagery in the design file may be used to create a map of the facility 102.

The facility map may only show a subset of the imagery in the design file.

Referring again to FIG. 1, at 14, the vector image is rasterized to generate a raster image. This may include the application of a rasterization algorithm configured to take an image described in a vector graphics format and convert it into a raster image.

At 16, a simplified geometry image is generated from the raster image. The simplified geometry image includes some elements of the raster image and excludes others.

The simplified geometry image may be generated using neural network-based processing and vectorization.

The neural network may be configured to receive the raster image as an input and generate a simplified geometry image as an output. The neural network is trained to discriminate between important features and unimportant features in the raster image and generate an output including only the important images. The output of the neural network includes noise. The noise includes image features or elements which have been determined by the network to be important and thus included, but which are not “important features” in the sense that they should not be included in the output of the method 10 (i.e. the reduced representation).

The simplified geometry image outputted by the neural network is vectorized to generate a new vector representation of the simplified geometry. Vectorization may include the application of a vectorization algorithm such as marching squares to the neural network simplified geometry image.

The new vector representation may look visually similar to a subset of the original geometry (i.e. the geometry in the input vector image).

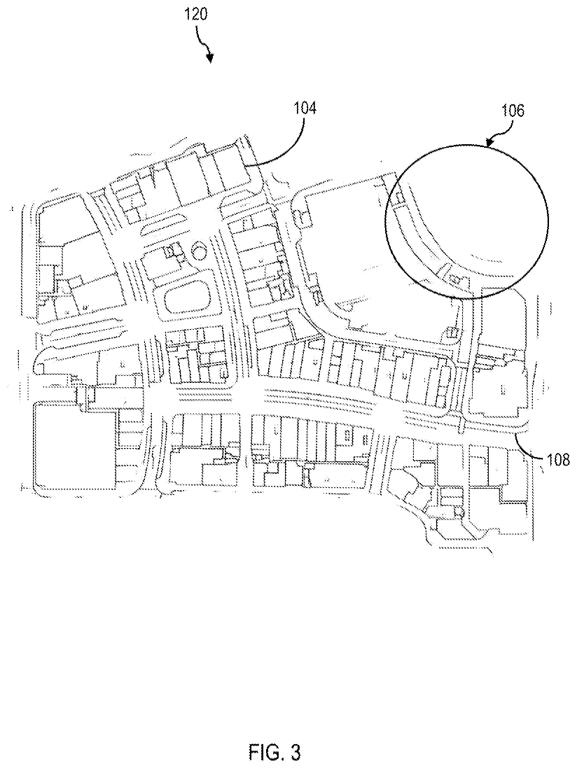

An example output of step 16 is shown in FIG. 3. FIG. 3 illustrates an example simplified drawing 120. The simplified drawing 120 is generated based on the original drawing 100 shown in FIG. 2.

The simplified drawing 120 is created by a neural network that has been trained to identify “important” features. For example, the neural network may be trained using training data including input images that have been labelled by humans. In particular, the training data may include images which include features that have been labelled “important” by human agents. Through the training process and using the training data, the neural network learns to discriminate between important and unimportant features in the input images.

For example, the simplified drawing 120 includes the “important” indoor areas of the shopping facility such as store unit 104.

The simplified drawing 120 does not include the “unimportant” outdoor features of the shopping facility, such as parking spaces, roads, and vacant land.

While the simplified drawing 120 includes important features, it also includes noise. For example, the simplified drawing 120 includes line segments (representative line segment 108 is shown) that do not form part of an “important” feature.

Further, the simplified drawing 120 may lose resolution compared to the original drawing 100 of FIG. 2. An example of such reduced resolution can be seen, for example, in region 106.

Referring again to FIG. 1, at 18, a filtered image (i.e. the reduced representation of the source data) is generated by mapping the new vector representation of the simplified geometry to the original vector image. This may include the application of morphological buffering and filtering techniques.

The filtering process may be designed to filter the source content without losing the accuracy of underlying encoded geometric relationships.

The filtered image generated at 18 includes a subset of the original geometry from the input vector image (provided at 12). Advantageously, as the filtered image includes a subset of the original geometry, the filtered image may be used to generate a map or diagram of the facility that is true to a real-world instantiation.

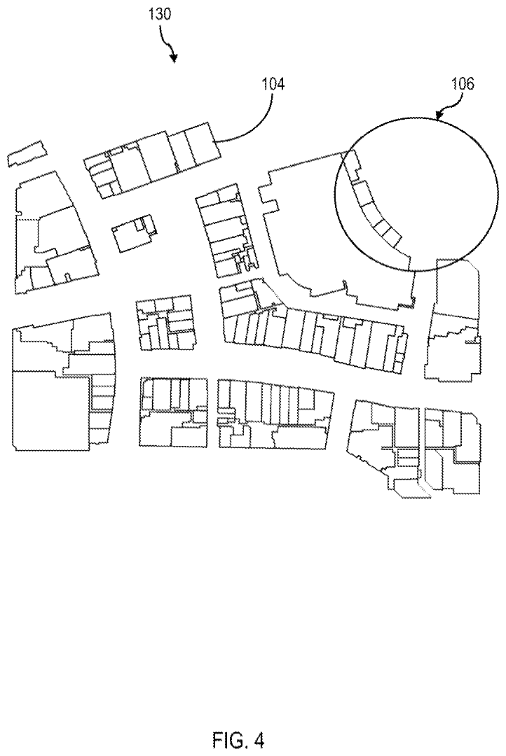

An example output of step 18 is shown in FIG. 4. FIG. 4 illustrates an example filtered drawing 130. The filtered drawing 130 is based on a comparison of the simplified drawing 120 (shown in FIG. 3) with the original drawing 100 (shown in FIG. 2).

The filtered drawing 130 includes an original geometry subset comprising a subset of the original geometry present in the original drawing 100. The original geometry subset includes the “important” features identified in the simplified drawing 120 that are confirmed to be in the original drawing 100. The original geometry subset does not include other features in the original drawing 100 that are not deemed “important.”

Furthermore, the vector imagery used to construct the filtered drawing 130 is taken from original drawing 100, rather than the simplified drawing 120. This may maintain good resolution. This improved resolution capability can been seen when comparing region 106 in FIGS. 2-4.

Further, the geometric relationships between features in the original drawing 100 are maintained in the filtered drawing 130.

The filtered drawing 130 may thus be used to create a map of the facility showing the “important” features.

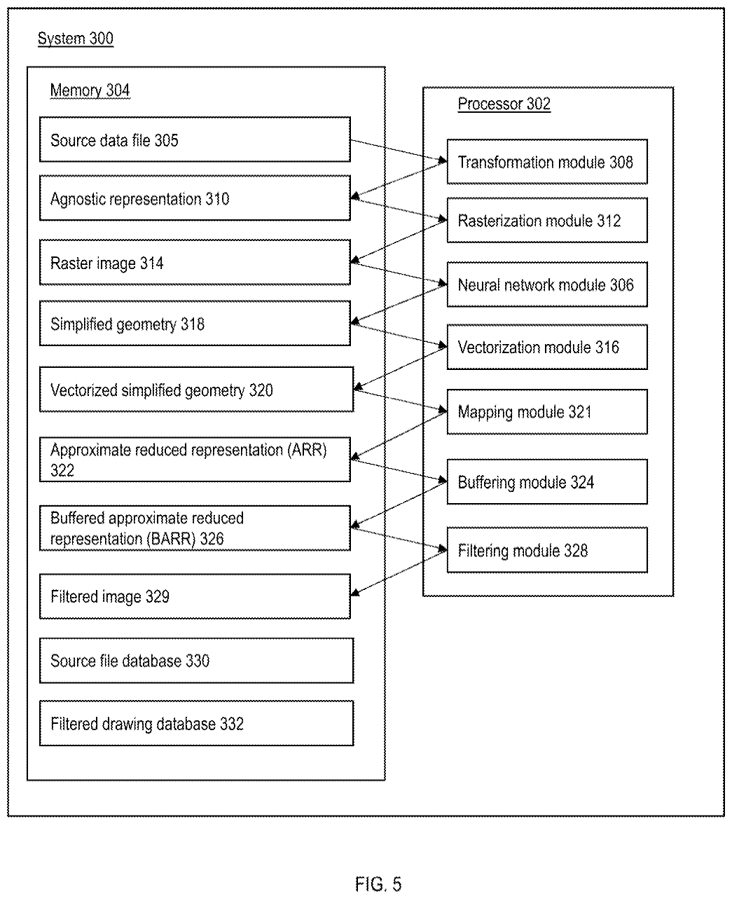

Referring now to FIG. 5, illustrated therein is a system 300 for geometry simplification and filtering, according to an embodiment.

The system 300 components may be hosted on one or more servers that are operably connected.

The system 300 is a computerized system and includes a computer processor 302 operably coupled to a memory 304.

The processor 302 may be a graphics processing unit (GPU) with designated onboard memory and architecture for implementing deep machine learning neural networks, for example, NVIDIA Titan RTX.

The memory 304 may be any volatile or non-volatile memory or data storage components including GPU onboard memory, random access memory (RAM), read-only memory (ROM), hard disk drives, solid state drives, USB flash drives, memory cards accessed via a memory card reader, optical discs accessed via an optical disc drive, or a combination of any two or more of these memory components.

The processor 302 includes a plurality of modules comprising computer-executable instructions which, when executed by the processor 302, cause the system 300 to perform the various operations and provide the various functionalities described herein. In this respect, the term “executable” means a program file that is in a form that can be run by the processor 302. Examples of executable programs may be, for example, a compiled program that can be translated into machine code in a format that can be loaded into a random access portion of the memory 304 and run by the processor 302, source code that may be expressed in proper format such as object code that is capable of being loaded into a random access portion of the memory 304 and executed by the processor 302, or source code that may be interpreted by another executable program to generate instructions in a random access portion of the memory 304 to be executed by the processor 302, etc.

The memory 304 stores 300 databases 330, 332 for storing a plurality of drawing files.

The source file database 330 stores original drawing source files (e.g. source data file 305). The original drawing source files include vector image data.

The filtered drawing database 332 stores filtered drawings (e.g. filtered image 329, described below) that are generated by the system 300.

The databases 330, 332 comprise data storage components, for example, hard disk drives, solid state drives, USB flash drives, memory cards accessed via a memory card reader, optical discs accessed via an optical disc drive, or a combination of any two or more of these data storage components.

The processor 302 includes a transformation module 308. The transformation module 308. The transformation module 308 is configured to transform a vector image in an original drawing source file 305 into an agnostic representation 310. The agnostic representation 310 is a generic geometry collection of the vector imagery in model space. The agnostic representation 310 is stored by the memory 304.

The processor 302 includes a rasterization module 312. The rasterization module 312 is configured to implement to perform scaling/mapping to generate a raster image 314 from the agnostic representation 310. The raster image 314 is stored by the memory 304 as a 3×3 invertible matrix, T.

The processor 302 includes a neural network module 306. The neural network module 306 includes a neural network. The neural network 306 may be a generative adversarial network. The neural network 306 may be a conditional generative adversarial network (cGAN). The neural network may be a cGAN suitable for high resolution image processing. In an embodiment, the neural network is Pix2PixHD. The neural network may be effective at discriminating feature-poor line art, such as black and white or greyscale images.

As described, the neural network module 306 may be configured to implement a cGAN. The cGAN may include two competing neural networks. The two competing neural networks may include a generator network and a discriminator network. The generator network is configured to create “forgeries” based on training data. The discriminator network seeks to correctly identify the “forgeries” from true examples in the training set. A human trainer may score the success (or failure) of the discriminator network to correctly separate forgeries from true examples. The scoring may be fed back to iteratively tune both the discriminator network and the generator network.

The use of a cGAN in the neural network module 306 may provide certain advantages. For example, the generator and discriminator networks may be conditioned on auxiliary information in addition to the vector imagery training data. The auxiliary information may include, for example, class labels or layers that are present in architectural design files. As a result, the network can learn multi-modal mapping, which may further aid in discriminating important features in drawing files. Further, the cGAN class of neural networks may perform tasks like converting object to outline or outline to object well and thus may be particularly well suited to geometry simplification (e.g. CAD simplification) and region understanding problems.

Embodiments in which the neural network module 306 includes a Pix2PixHD network may be particularly advantageous in processing architectural drawing files or other drawing files with greyscale line art. This is because Pix2PixHD may be particularly effective at discriminating feature-poor (e.g. black/white or greyscale) line art compared to conventional convolutional neural networks. In variations, the system 300 is configured to process architectural drawing files, which typically include greyscale line art.

The neural network 306 is thus trained to identify “important” features in the raster image 314 based on learning “forgery” training images and true examples that have “important” features as labelled by human trainers. For example, “important” features may be fully enclosed polygons in the raster image 314 which correspond to store units in the original drawing of the facility.

The “important” features form the simplified geometry 318 that is output of the neural network 306 and stored by the memory 304.

The processor 302 includes a vectorization module 316. The vectorizing module 316 is a set of processor-executable instructions for applying an algorithm to the simplified geometry 318 to generate a vectorized simplified geometry 320. The vectorized simplified geometry 320 is stored by the memory 304.

The processor 302 includes a mapping module 321. The mapping module 321 is configured to generate an approximate reduced representation (ARR) 322 from the vectorized simplified geometry 320. The mapping module 321 is configured to map the vectorized simplified geometry 320 into the model space coordinate system. This may include applying an inverse of the transform used to map into the image space (i.e. T⁻¹) The ARR 322 is the inverse transformation of the vectorized simplified geometry 320. The ARR 322 is in the original coordinate system of the vector image.

The processor 302 includes a buffering module 324. The buffering module 324 is a set of processor-executable instructions for morphologically buffering the ARR 322 to generate a buffered approximate reduced representation (BARR) 326. The BARR 326 is stored by the memory 304.

The processor 302 includes a filtering module 328. The filtering module 328 is a set of processor-executable instructions for comparing the BARR 326 and the original drawing in the source file (e.g. drawing 100) to generate a filtered image 329. The filtered image 329 is stored in the filtered drawing database 322.

Referring to FIG. 5, illustrated therein is a flow chart of a method 200 for automated geometry simplification and filtering, according to an embodiment.

The method 200 may be used to simplify and filter the geometric information in drawing source files (e.g. CAD, SVG, DXF, DWG, .AI, EPS) to identify important features which can then be used to create maps that are true to real world instantiations.

The method 200 may be performed by components of the system 300 of FIG. 4. The components from FIG. 4 are identified in parenthesis for reference.

At 202, a vector imagery source file (e.g. source file 305 of FIG. 5) is transformed into an agnostic representation (310) according to transformation module (308).

The agnostic representation (310) is a generic geometry collection of the source file vector imagery in model space. The agnostic representation (310) is initially used to generate a raster image (314), at 204, to pass through a trained neural network (306), at 206. The agnostic representation (310) is ultimately filtered, at 214, to create a filtered drawing that is stored in the database (332).

At 204, a raster image (314) is generated from the agnostic representation (310) according to rasterization module (312).

The rasterization module (312) preferably includes instructions to generate a 2048×2048 raster image (314) from the generic geometric data in the agnostic representation (310), although other dimensions are possible.

Mapping from the coordinate system of the generic geometry (in model space) to the raster image (in image space) is performed by scaling the agnostic representation (310) so that the agnostic representation dimensions in x and y equal 2048, then translating so that the resulting geometry is centered in the image space. This results in a rigid transformation that can be represented as a 3×3 invertible matrix, T.

At 206, the raster image (314) is passed through a trained neural network (306) to generate simplified geometry (318).

The neural network is trained to identify the “important” features in the raster image (314), and output simplified geometry (318) corresponding to those important features, in the image space. Features deemed not to be important are excluded from the simplified geometry (318).

At 208, the simplified geometry (318) is vectorized according to vectorization module (316).

The vectorization module (316) applies an algorithm, for example, marching squares to the simplified geometry (318). This results in a reduced representation in the coordinate system of the image space that is likely to look visually similar to a subset of the original geometry. That is, the vectorized simplified geometric appears visually similar to the “important” features in the source file. For example, FIG. 3 shows the vectorized simplified geometry (320) of the “important” features of the original vector image in FIG. 2.

At 210, an approximate reduced representation (ARR, 322) of the vectorized simplified geometry (320) is generated in model space. This is achieved by applying the inverse of the transform used to map into the image space at 204 (i.e. T⁻¹), to map the vectorized simplified geometry (320) into the model space coordinate system. This results in an ARR (322) that is in the original coordinate system of the original drawing source file. The ARR (322) may then be leveraged to filter the original source file content without losing the accuracy of underlying encoded geometric relationships (i.e. relative positions of original geometry in the source file vs. the relative positions of simplified geometry in the model space are maintained).

At 212, morphological buffering is applied to the ARR (322) to generate a buffered approximate reduced representation (BARR, 326). The morphological buffering is done according to buffering module (324), preferably using epsilon >0.

At 214, the BARR (326) is filtered to a subset of the original geometry in the source file according to filtering module (328). Filtering generally involves comparing the BARR (326) and the original geometry in one of two ways. Fidelity to the source file is maximized by removing line segments from the original geometry that do not sufficiently intersect the BARR (326), yielding a filtered drawing (332) that includes subset of line segments from the original geometry (as shown in FIG. 3). Alternatively, filtering may involve limiting the result to the intersection of the original geometry with the BARR (326), subject to the caveat that the resulting subset of geometry may no longer map 1 to 1 to line segments in the source file (i.e. line segments may be split into multiple disjointed segments) and resulting segments may be proper subsegments of the parent geometries in the source file.

Regardless of which filtering is applied at 214, the result is a filtered drawing (322) showing “important” feature geometry that is a subset of the source file original geometry. The subset of the source file original geometry maintains the geometric relationship between features. The filtered drawing is stored in the database (322). The filtered drawing 322 may be then used to creating facility maps that are true to real world instantiations.

While the above description provides examples of one or more apparatus, methods, or systems, it will be appreciated that other apparatus, methods, or systems may be within the scope of the claims as interpreted by one of skill in the art.

1. A system for geometry simplification and filtering in architectural drawings, comprising:
a processor; and
a memory operably coupled to the processor, and having stored thereon processor-executable instructions that, when executed, cause the processor to:
transform vector imagery into an agnostic representation;
generate a raster image, whereby the coordinate system of the agnostic representation is mapped and scaled to an image space;
generate a simplified geometry from the raster image;
vectorize the simplified geometry in the coordinate system of the image space;
generate an approximate reduced representation of the simplified geometry in model space;
apply morphological buffering to the approximate reduced representation to generate a buffered approximate reduced representation; and
filter the buffered approximate reduced representation to a subset of the vector imagery.

2. The computer-readable storage medium of claim 1, wherein the agnostic representation is a generic geometry collection of the vector imagery in model space.

3. The computer-readable storage medium of claim 1, wherein the vector imagery is a visual representation of any one of: a facility, an architectural structure and a physical object.

4. The computer-readable storage medium of claim 1, wherein the approximate reduced representation is the inverse transform of the simplified geometry in the original coordinate system of the vector imagery.

5. A computer-implemented method for geometry simplification and filtering in architectural drawings, comprising:
transforming vector imagery into an agnostic representation;
generating a raster image, whereby the coordinate system of the agnostic representation is mapped and scaled to an image space;
generating a simplified geometry from the raster image by a neural network trained to discriminate between important features and unimportant features in the raster image;
vectorizing the simplified geometry in the coordinate system of the image space;
generating an approximate reduced representation of the simplified geometry in model space;
applying morphological buffering to the approximate reduced representation to generate a buffered approximate reduced representation; and
filtering the buffered approximate reduced representation to a subset of the vector imagery.

6. The method of claim 5, further comprising storing the buffered approximate reduced representation in a database.

7. The method of claim 5, wherein the vector imagery is a visual representation of any one of: a facility, an architectural structure and a physical object.

8. The method of claim 5, wherein the agnostic representation is a generic geometry collection of the vector imagery in model space.

9. The method of claim 5, wherein the raster image has dimensions of 2048×2048 pixels.

10. The method of claim 9, wherein the raster image is stored as a 3×3 invertible matrix.

11. The method of claim 5, wherein the trained neural network is a generative adversarial network or a conditional generative adversarial network.

12. The method of claim 5, wherein the approximate reduced representation is the inverse transform of the simplified geometry in the original coordinate system of the vector imagery.

13. The method of claim 5, wherein the morphological buffering is applied using an epsilon value >0.

14. The method of claim 5, wherein filtering the buffered approximate reduced representation comprises removing line segments from the vector imagery that do not sufficiently intersect the buffered approximate reduced representation.

15. The method of claim 5, wherein filtering the buffered approximate reduced representation comprises limiting the subset of the imagery to the intersection of the vector imagery and the buffered approximate reduced representation.

16. A computer-implemented method for geometry simplification and filtering, comprising:
generating a raster image from a vector image;
generating a simplified image from the raster image by a neural network trained to discriminate between important features and unimportant features in the raster image; and
generating a filtered image by mapping one or more features of the simplified image to the vector image.

17. The method of claim 16, wherein the vector image is a visual representation of any one of: a facility, an architectural structure and a physical object.

18. The method of claim 16, wherein the neural network is trained to discriminate between important features and unimportant features by implementing a conditional generative adversarial network.

19. The method of claim 16, wherein the simplified image includes only important features.

20. The method of claim 16, wherein the vector image lacks any one or more of: color and texture.
